(19) United States
(12) Patent Application Publication
(10) Pub. No.: US 2025/0244080 A1
(43) Pub. Date: Jul. 31, 2025

(54) HEAT TRANSFER SYSTEM

(71) Applicant: City St George's, University of London, London (GB)

(72) Inventor: Qiang ZHANG, London (GB)

(73) Assignee: City St George's, University of London, London (GB)

(21) Appl. No.: 19/102,203

(22) PCT Filed: Aug. 8, 2023
(86) PCT No.: PCT/EP2023/071925

§ 371 Date: Feb. 7, 2025

(30) Foreign Application Priority Data
Aug. 8, 2022 (GB) 2211534.9

(51) Int. Cl. F28D 1/02; F04D 29/38; F04D 29/58; F24F 13/30; F28D 1/047; F28D 11/02

(52) U.S. Cl. CPC F28D 1/024; F04D 29/388; F04D 29/5826; F24F 13/30; F28D 1/0472; F28D 11/02

(57) ABSTRACT

A heat transfer system (1) comprising: a fan (3), and a heat exchanger (5) arranged relative to the fan (3) so that the fan (3) is operable to blow or draw air over and/or through the heat exchanger (5), wherein the fan (3) and the heat exchanger (5) each include an internal pathway through which working fluid can flow, the respective internal pathways being coupled to one another so that working fluid can flow through the fan (3) and the heat exchanger (5) for heat transfer between the working fluid and the air.

### FIELD

This disclosure relates, in one aspect, to a heat transfer system. In one illustrative implementation of the teachings of this disclosure, the heat transfer system disclosed herein may form part of an air source heat pump heating system. More generally, the heat transfer system disclosed herein finds utility in any system that requires heat transfer between a working fluid within the heat transfer system and the ambient environment.

Although the heat transfer system disclosed herein is described in detail below in the context of an air source heat pump heating system, it should be remembered that the teachings of this disclosure are not limited solely to this particular application and that the heat transfer system herein disclosed may be employed in a variety of systems where heat transfer is required.

### BACKGROUND

Over the last few decades it has become ever more apparent that humanity needs to move away from generating energy from fossil fuel energy resources if the effects of global warming are to be mitigated. Recent spikes in the cost of fossil fuels, notably oil and gas, have helped focus consumers' minds on switching to environmentally friendlier solutions.

One environmentally friendlier alternative to conventional gas fired boilers that has recently championed by Her Majesty's Government is the so-called air source heat pump. Air source heat pumps, as the name implies, draw heat from the ambient environment and supply that heat to the home or workplace. Air source heat pump systems typically employ a heat transfer system that comprises a fan that is arranged to draw or blow air over an adjacent evaporator.

One significant factor affecting the Coefficient of Performance (COP) of an air source heat pump system is how well heat can be transferred between the working fluid and the ambient environment by the heat transfer system. One way to improve heat transfer would be to make the evaporator larger (i.e. increase the heat transfer area), but doing this in a domestic environment might not be feasible as space is often limited. Another way to improve heat transfer would be to run the fan that blows or draws air over the evaporator at a higher speed, but as this would increase the noise generated by the unit it is often not tolerable in a domestic environment.

Aspects of the heat transfer system disclosed herein have been devised with the foregoing in mind.

### SUMMARY

One presently preferred aspect of this disclosure provides a heat transfer system comprising a fan, and a heat exchanger arranged relative to the fan so that the fan is operable to blow or draw air over and/or through the heat exchanger, wherein the fan and the heat exchanger each include a pathway through which working fluid can flow, the respective pathways being coupled to one another so that working fluid can flow through the fan and the heat exchanger to enable heat transfer between the working fluid and the air.

One illustrative advantage of this arrangement is that the area available for heat transfer is increased, relative to a conventional heat transfer system, without having to increase the footprint of the heat transfer system. Another advantage is that the efficacy of heat transfer is improved, as compared with a conventional heat transfer system, without increasing the noise generated by the fan by running it at a higher speed.

In a preferred implementation the fan comprises: a hollow axle, a hollow hub fluidly coupled to the axle so that working fluid can flow through the axle and the hub, and a plurality of blades extending radially from the hub; at least said axle being of a heat conducting material so that heat transfer can occur between working fluid flowing through said axle and the air.

Optional features of other contemplated implementations of the teachings of this disclosure are as follows:
The hollow hub and/or said blades may be of a heat conducting material;
At least one of said blades may be hollow and fluidly coupled to said hub so that working fluid can flow into and out of said hollow blade for heat transfer with the air;
One or more of said blades may include an internal blade pathway through which working fluid can flow;
said internal blade pathway may include a plurality of perturbators operable to increase perturbations in working fluid flowing through the internal blade pathway;
said internal blade pathway may be serpentine;
said blade may comprise one or more internal walls, said internal walls being configured to provide an internal blade pathway that is serpentine in one dimension within said blade;
said blade may have a leading edge and a trailing edge, and said internal blade pathway may be serpentine in one dimension that extends lengthwise between said leading edge and said trailing edge;
said blade may comprise a plurality of more internal walls, said internal walls being configured to provide an internal blade pathway that is serpentine in two dimensions within said blade;
said blade may have a leading edge, a trailing edge, and first and second sidewalls extending between said leading and trailing edges; said internal blade pathway may be serpentine in a first dimension that extends longitudinally between said leading edge and said trailing edge, and in a second dimension that extends transversely between said first and second sidewalls;
said internal blade pathway may comprise an inlet for ingress of working fluid and an outlet for egress of working fluid;
said inlet may be located in a first blade and said outlet may be located in a second blade that is radially spaced from said first blade so that said internal blade pathway extends through more than one blade;
said inlet and said outlet may be located in the same blade so that said internal blade pathway extends through a single blade;
said hub may include an internal baffle that subdivides said hollow hub into a first manifold on one side of said baffle and a second manifold on the other side of said baffle, each said manifold may include a plurality of ports at spaced locations about a peripheral wall of the hub;
said ports may enable fluid communication between said hub and the inlet and the outlet of said internal blade pathway;
a port in said first manifold may be in fluid communication with said inlet, and a port in said second manifold may be in fluid communication with said outlet;
sidewalls of one or more of said blades may be provided with a plurality of ribs;
an external surface of said hub may be provided with a plurality of ribs;
said blades may include a rip region, and the tip region of at least one of said blades may comprise a winglet;
said heat exchanger may define a recess in which at least part of said fan is located;
said fan may be enclosed within a void defined inside said heat exchanger;
said heat exchanger may comprise a fluid permeable body, said internal pathway extending through said fluid permeable body;
said internal pathway through said heat exchanger may comprise a length of piping through which working fluid can flow for heat exchange between the pipe and the air;
the heat transfer system may comprise a plurality of vanes through which said length of piping extends, said vanes being thermally coupled to said piping;
said heat exchanger may comprise a plurality of vanes and said internal pathway may comprise a serpentine pathway extending through one or more of said vanes.

Another aspect of the present disclosure pertains to an HVAC, Air Source Heat Pump or ORC system comprising a heat transfer system of the type disclosed herein.

Other advantages and aspects of the heat transfer system disclosed herein will be apparent from the detailed description provided below.

### BRIEF DESCRIPTION OF THE DRAWINGS

The teachings of this disclosure, and arrangements embodying those teachings, will hereafter be described by way of illustrative example with reference to the accompanying drawings, in which:

FIG. 1 is a schematic rear isometric view of a heat transfer system that embodies the teachings of the present disclosure;

FIG. 2 is a schematic front isometric view of the heat transfer system shown in FIG. 1;

FIG. 3 is a rear elevation of the heat transfer system shown in FIGS. 1 and 2;

FIG. 4 is a cross-sectional view of the heat transfer system along the line A-A in FIG. 3;

FIG. 5 is an enlarged view of the region marked “B” in FIG. 4;

FIG. 6 is a schematic perspective view of an illustrative fan (impeller) of the heat transfer system shown in FIGS. 1 and 2;

FIG. 7 is a longitudinal (i.e. end to end) elevation in cross-section of an illustrative blade for the fan of FIG. 6;

FIG. 8 is a transverse (i.e. side to side) elevation in cross-section of the blade shown in FIG. 7;

FIG. 9 is a longitudinal (i.e. end to end) elevation in cross-section of another illustrative blade for the fan of FIG. 6, and

FIG. 10 is a transverse (i.e. side to side) elevation in cross-section of the blade shown in FIG. 9.

### DETAILED DESCRIPTION

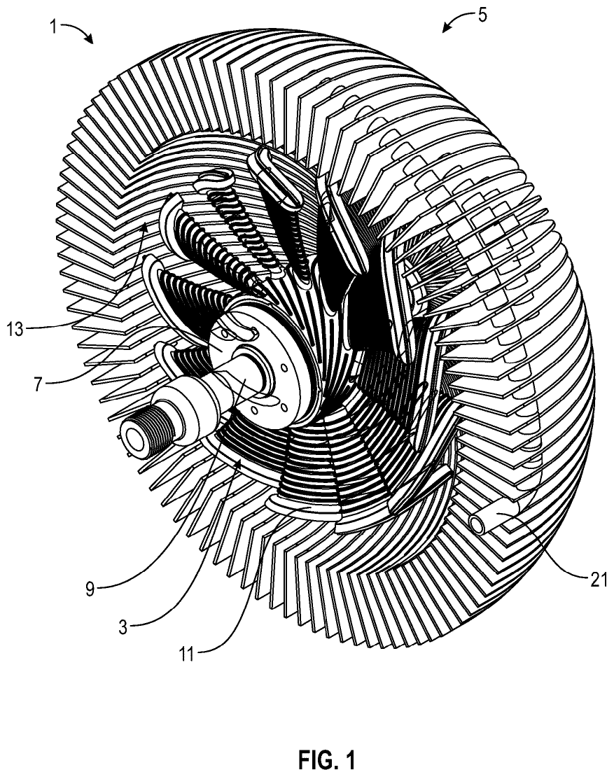

Referring now to FIGS. 1 to 3 of the accompanying drawings, the heat transfer system 1 of the present disclosure comprises a fan 3 and a heat exchanger 5. The fan 3 comprises a hub 7 that is coupled to an axle 9 (one end of which is visible) for rotation therewith. A plurality of blades 11 extend radially outwardly from the hub 7.

In this particular arrangement the heat exchanger 5 is generally bowl-shaped and defines a recess 13 within which the hub 7 and blades 11 of the fan 3 lie. This arrangement is advantageously particularly compact as the heat exchanger doubles up as a safety shield by obstructing access to the fan when the heat exchanger is coupled to a support surface (such as a cabinet housing other components of an air source heat pump, for example). Whilst this arrangement has advantages, it will be appreciated that it is not essential for the heat exchanger to be bowl-shaped or, indeed, for the fan to be within a void defined by the heat exchanger. In an alternative arrangement the heat exchanger could comprise a rectangular cuboid or cuboid body that the fan is arranged to draw or blow air through and/or over.

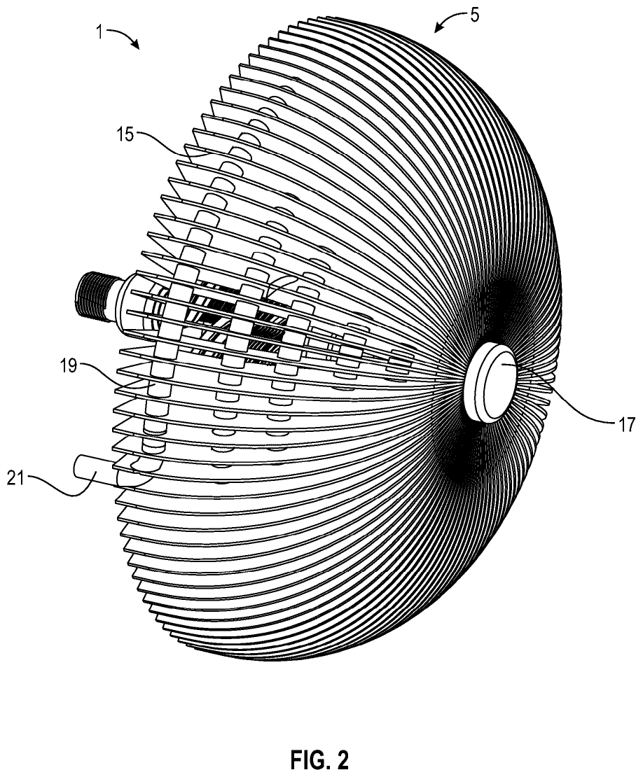

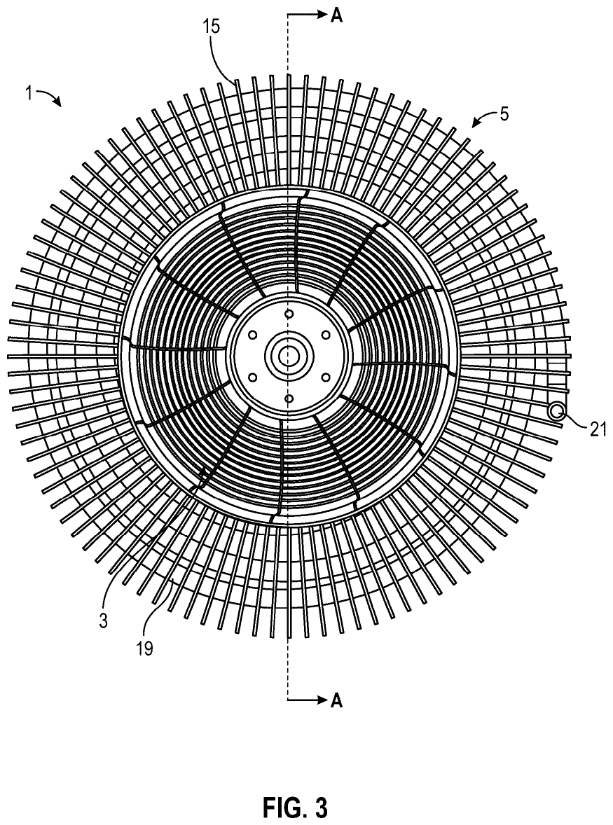

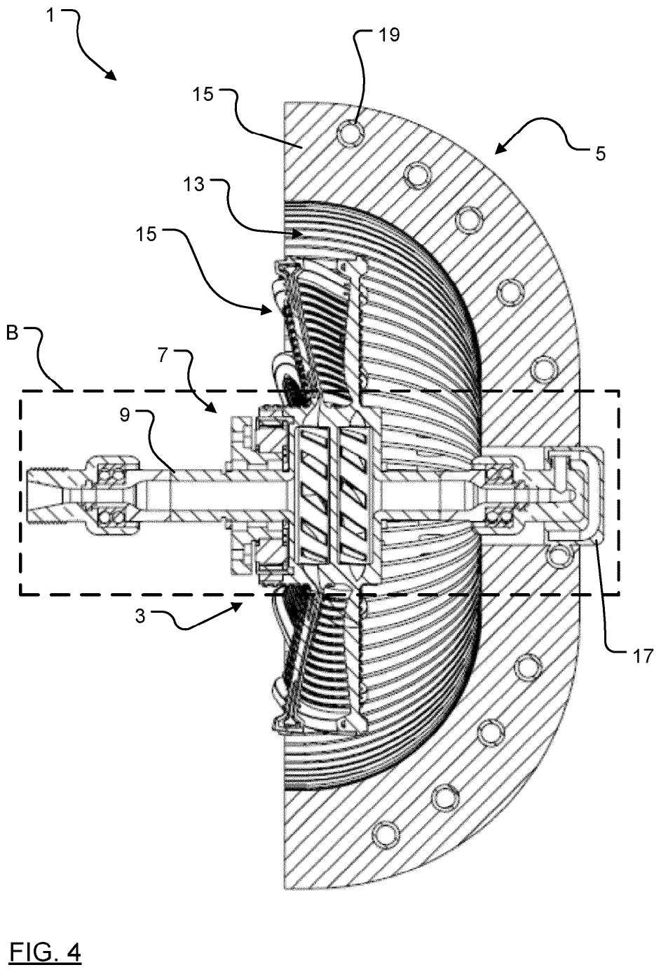

The heat exchanger 5 comprises a plurality of vanes 15 of heat conductive material that extend radially outwardly from a cap 17 (FIG. 2). In this arrangement, the vanes are each provided with a plurality of apertures 19 (best shown in FIG. 4) that co-operate to define a coiled internal passageway through the heat exchanger towards the cap 17. A coiled pipe 21 (best shown in FIG. 3 where the pipe has been shaded so that it can be seen more clearly) of heat conductive material extends from a port 23 through the coiled passageway towards the cap 17, and is closely coupled to each of the vanes for heat transfer between the pipe and the vanes. The pipe 19, as will be immediately apparent to persons of skill in the art, provides the heat exchanger with an internal fluid pathway through which a working fluid can flow.

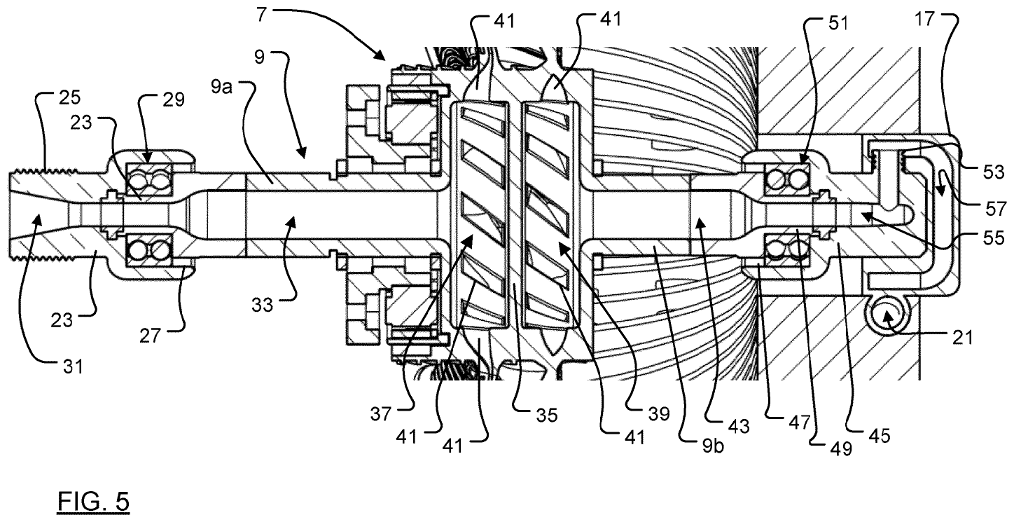

FIG. 5 shows an enlarged view of the area labelled “B” in FIG. 4. As shown in FIG. 5, a heat transfer system support 23 includes an outwardly threaded tail 25 so that the heat transfer system support 23 can be securely engaged with a support surface (not shown) such as a wall of a cabinet in which at least part of the heat transfer system is located. The heat transfer system support 23 has an enlarged open end that defines a recess 27 in which a reduced diameter portion 23 of a first part 9a of the axle 9 is received. A bearing 29 is provided between the heat transfer system support 23 and the reduced diameter portion 23 of the axle 9 so that the axle can rotate relative to the heat transfer system support 23. The heat transfer system support 23 includes a bore 31 that is in fluid communication with an internal bore 33 of the axle 9.

The hub 7 includes an internal baffle 35 that co-operates with the remainder of the hub to define a void that functions as a first fluid manifold 37 and a void that functions as a second fluid manifold 39 within the hub 7. Each manifold includes a plurality of ports 41 that are in fluid communication with serpentine internal pathways provided inside of the blades 11.

In one envisaged arrangement, each port of the first and second manifolds are in fluid communication with only one of the blades 11 so that a given port in one of the first and second manifolds provides an entrance to the serpentine fluid pathway of a blade for the ingress of working fluid, and a corresponding port in the other of the first and second manifolds provides an exit from the serpentine fluid pathway of that blade for the egress of working fluid.

In one implementation, working fluid enters the heat transfer system via the support 23 and flows via the axle 9 to the first fluid manifold 37, and thence from the first fluid manifold into the blades 11. Working fluid circulates through the serpentine internal pathways provided within the blades before exiting the blades and flowing into the second fluid manifold 39. In this configuration, with the fan rotating in a clockwise direction, fluid in the first fluid manifold is at a higher pressure than fluid in the second fluid manifold and components to the left of the baffle 35 (as shown in FIG. 5) are hence said to be on the “pressure” side of the system, whereas components to the right of the baffle 35 (again, as shown in FIG. 5) are said to be on the “suction” side of the system. If the fan were to be run in the opposite direction, then the “pressure” and “suction” sides of the system would be reversed.

Referring again to FIG. 5, the second fluid manifold is in fluid communication with an internal bore 43 of a second part 9b of the axle 9. The cap 17 co-operates with a fan support 45 that has an enlarged open end which defines a recess 47 in which a reduced diameter portion 49 of the second part 9b of the axle 9 is received. A bearing 51 is provided between the fan support 45 and the reduced diameter portion 49 of the axle 9 so that the axle can rotate relative to the fan support 45.

The fan support 45 includes a port 53 that is in fluid communication with an internal bore 55 within the fan support 45. The port 53 opens to an internal void 57 within the cap 17, and the cap internal void 17 is in fluid communication with the pipe 21 passing through the apertures 19 in the vanes 11 of the heat exchanger 5.

As will be appreciated by persons skilled in the art, working fluid entering the heat transfer system support can flow through the first part of the axle, and thence through the blades of the fan. This allows the fan blades to assist in the transfer of heat between the working fluid and the ambient air. Once the working fluid has passed through the blades, it can then pass via the other part of the axle and the fan support to the coiled pipe that is in thermal contact with the vanes of the heat exchanger, and heat can be exchanged between the working fluid and the ambient air as the fluid moves through the pipe towards port 23.

By virtue of this arrangement heat exchange can take place between the vanes of the heat exchanger and the blades of the fan (and optionally between other components of the fan), thereby improving heat exchange as compared with a conventional heat transfer system where heat exchange only occurs between the evaporator and the ambient air. Specifically, in the arrangements disclosed herein fan blade tip leakage flow, hub secondary flow, and other separated flows near the blade surfaces can all contribute to the enhancement of heat transfer. Advantageously, this improvement is provided without having increase the operating noise by running the fan at a higher speed than a conventional heat transfer system.

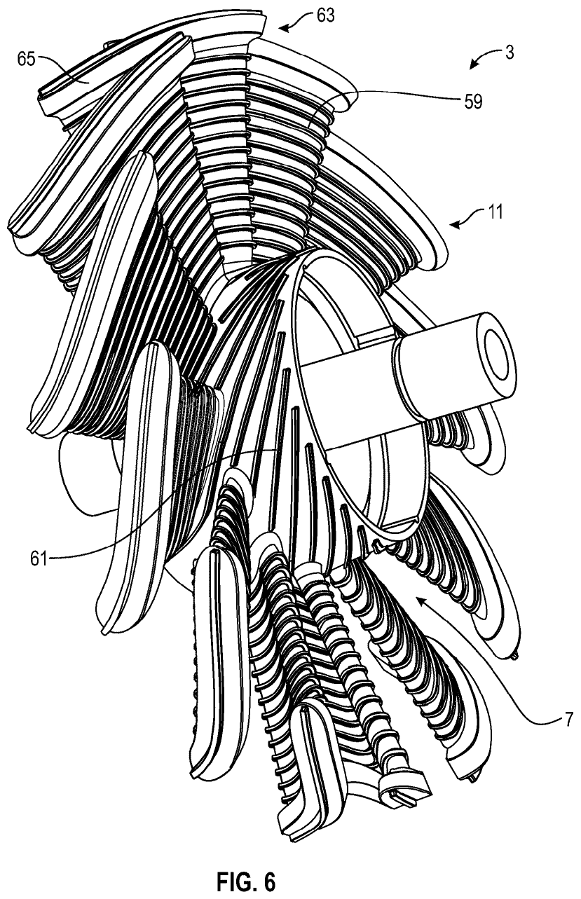

Referring now to FIG. 6 of the drawings, in one envisaged implementation the blades 11 of the fan have an aerofoil shape so that the ambient air is effectively accelerated towards the heat exchanger. It is also envisaged to provide one or more of the blades (or in this particular example, all of the blades) with a plurality of ribs 59 that project outwardly from the outer surface of the blade. The ribs 59, if provided, provide a number of benefits. In the first instance, the ribs 59 provide an aerodynamic benefit by aligning the main flow direction and reducing secondary flow. The ribs also increase the area available for heat transfer, and act as turbulators which enhance the local heat transfer rate.

As depicted in FIG. 6, an external surface of the hub 7 may alternatively or additionally be provided with ribs 61 that enhance the capabilities of the heat transfer system in the same way as the ribs 59 on the blades, for example by enhancing horseshoe vortex flow structures near the hub.

In one implementation it is proposed to provide tips 63 of the blades with winglets 65 that provide an aerodynamic benefit by reducing leakage flow around the fan. The winglets 65 also increase the area available for local heat transfer, and may be provided as well as or instead of the ribs on the blades and/or the hub. An implementation with winglets provides significant heat transfer benefits as tip leakage flow offers the highest velocity magnitude as well as three dimensional vortical turbulent flow structures.

It is also envisaged for the hub, and optionally the axle, to be manufactured from a heat conductive material. In a particularly advantageous implementation, additive fabrication methods may be employed to manufacture some or all of the components of the fan, and some or all of the heat exchanger 5. In one envisaged implementation, the heat conductive material may comprise a metal or metal alloy, but it will be appreciated by persons skilled in the art that benefits may accrue by manufacturing at least the axle of the fan from any material that heats up when it comes into contact with a (relatively) warmer working fluid, and as a consequence “heat conductive material” should be construed accordingly.

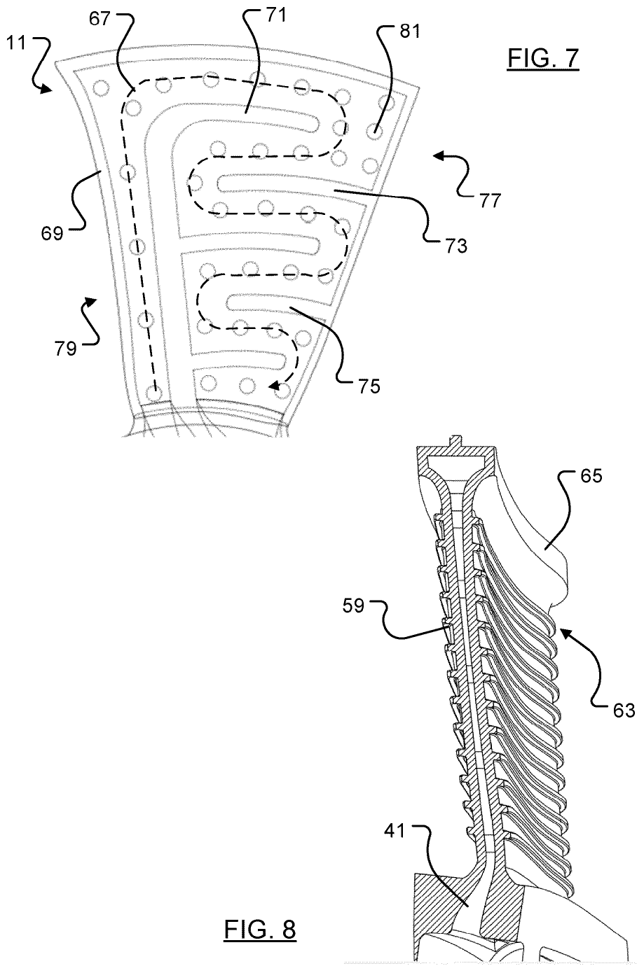

FIG. 7 is a longitudinal (i.e. end to end) elevation in cross-section of an illustrative blade for the fan of FIG. 6, and FIG. 8 is a transverse (i.e. side to side) elevation in cross-section of the blade shown in FIG. 7.

As mentioned above, the ports 41 in the first and second fluid manifolds 37,39 provide access to a serpentine internal pathway 67 within the blades 11 of the fan 3. The serpentine internal pathway is defined by an external peripheral wall 69 of the blade 11, a generally E-shaped internal wall 71, and two internal walls 73 and 75 that extend between the walls of the E-shaped internal wall 71 from a part of the external wall 69 that forms a trailing edge 77 of the blade 11 towards a part of the external wall 69 that forms a leading edge 79 of the blade 11. Advantageously, this configuration of serpentine internal pathway guides working fluid through the leading edge 79 and tip region 63 of the blade where the rate of heat transfer between the working fluid and the ambient environment is high.

The blade may also be provided with a plurality of pegs 81 that span the serpentine internal pathway 67 in a transverse direction and are coupled to each sidewall of the blade. The pegs 81 function to strengthen the blade (particularly if the blade is formed by means of an additive manufacturing process) and also as perturbators which are capable of introducing perturbations to the working fluid flowing through the pathway, which perturbations help to increase the local rate of heat transfer between the working fluid and the ambient environment. Other types of perturbators, such as pegs or other features extending partway into the internal pathway may alternatively or additionally be provided.

It will be appreciated that the provision of serpentine pathways through the blades greatly increases the area available for heat transfer between the working fluid and the ambient environment. In a preferred arrangement the ports are arranged so that fluid passes into and out of all of the blades at the same time, as this tends to balance the weight of fluid flowing through the fan. In other contemplated arrangements, a serpentine fluid pathway may be provided that extends through more than one blade with an entrance in one fan blade and an exit in another adjacent or more circumferentially distant fan blade.

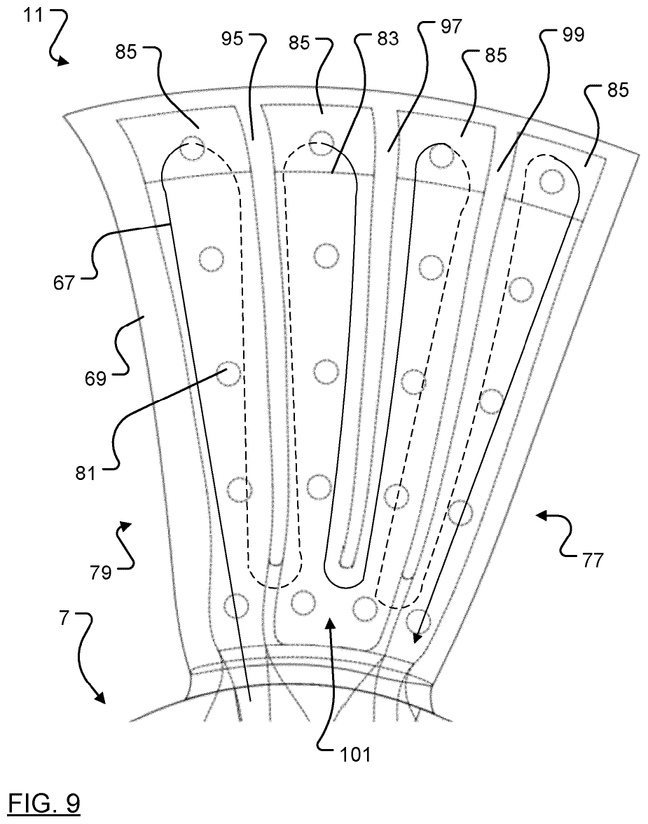

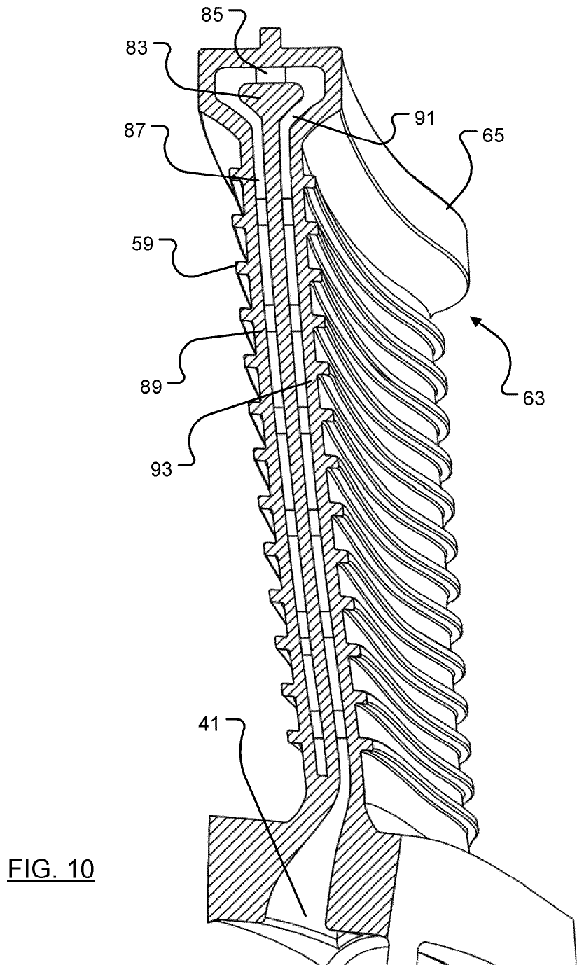

Referring now to FIGS. 9 and 10, FIG. 9 is a longitudinal (i.e. end to end) elevation in cross-section of another illustrative blade for the fan of FIG. 6 and FIG. 10 is a transverse (i.e. side to side) elevation in cross-section of the blade shown in FIG. 9. For brevity, features common to the blade shown in FIGS. 7 and 8 and the blade shown in FIGS. 9 and 10 are designated with the same reference numerals and will not be described again.

As can best be appreciated from FIG. 10, the blade 11 further comprises an longitudinal internal wall 83 running between the external peripheral walls 69 of the blade from the leading edge 79 to the trailing edge 77. As is best shown in FIG. 10, the internal wall 83 stops short of a top wall of the winglet 65 at spaced locations within the blade to provide passageways 85 for working fluid flow in a transverse direction between voids 87 defined between the internal wall 83 and a first sidewall 89 of the blade and voids 91 defined between the internal wall 83 and a second sidewall 93 of the blade.

In addition, to permit working fluid flow in a longitudinal direction the blade further comprises a plurality of transverse walls 95, 97 and 99 (FIG. 9) that are cut away sequentially to either side of the longitudinal internal wall 83 towards the hub 7. In the particular example shown in FIG. 9 and looking from the trailing edge 77 towards the leading edge 79, transverse wall 95 is cut-away on the right side of the longitudinal internal wall 83 (the cut-away portion being obscured in FIG. 9), transverse wall 97 is cut-away 101 on the left hand side of the longitudinal internal wall 83 (and hence is visible in FIG. 9), and transverse wall 99 is cut-away on the right hand side of the longitudinal internal wall 83 (and is again obscured in FIG. 9).

In the particular example shown in FIG. 9, and again looking from the trailing edge 77 of the blade towards the leading edge 79, working fluid can flow up the inside of the leading edge 79 on the left hand side of wall 83 through a void defined by the leading edge and transverse wall 95, over the top of wall 83, down the inside of the leading edge on the right hand side of wall 83 (shown by a dashed line) through a void defined by the leading edge and transverse wall 95, up into a void formed between transverse walls 95 and 97 on the right hand side of wall 83 (again shown by a dashed line), over the top of wall 83, down into a void formed between transverse walls 95 and 97 on the left hand side of wall 83, up into a void formed between transverse walls 97 and 99 on the left hand side of wall 83, over the top of wall 83, down into a void formed between transverse walls 97 and 99 on the right hand side of wall 83 (shown by a dashed line), up into a void formed between transverse wall 99 and the trailing edge 77 on the right hand side of wall 83 (again shown by a dashed line), over the top of wall 83, and into a void defined by transverse wall 99 and the trailing edge 77.

In summary, the principal difference between the blade shown in FIGS. 7 and 8 and the blade shown in FIGS. 9 and 10 is that in the FIG. 7 blade the serpentine internal pathway extends in one dimension (namely, back and forth longitudinally along the length of the blade), whereas in the FIG. 9 blade the serpentine internal pathway extends in two dimensions (namely, back and forth longitudinally along the length of the blade and transversely from side to side of the blade).

It will be apparent to persons skilled in the art from the foregoing that the heat transfer system herein disclosed provides a greater surface area for heat exchange than a conventional impeller and evaporator arrangement, which enables improvements in the efficiency of heat transfer. A number of additional improvements and advantages have been disclosed above. For example, whilst in conventional systems the fan merely propels air over the adjacent evaporator, the teachings of this disclosure provide skilled persons with greater design freedom, for example to enhance fan performance in terms of aerodynamics and/or heat transfer.

It will be appreciated that whilst various aspects and embodiments of the present disclosure have heretofore been described, the scope of the disclosure is not limited to the particular arrangements set out herein and instead extends to encompass all arrangements, and modifications and alterations thereto, which fall within the scope of the appended claims.

For example, whilst the heat transfer system has been described above in the context of an air source heat pump, the system disclosed may be employed in many other applications. For example, the system could be employed within a computing resource (such as a server or desktop computer, for example) to cool a CPU or GPU of the resource. The system could also be employed in air cooled HVAC chillers, ORC (organic rankine cycle) engines, or in battery powered electric vehicles. As such, references herein to air source heat pumps should not be construed as limiting the scope of the disclosure.

In another envisaged implementation, the potential for heat transfer may be enhanced, as compared with a conventional system, simply by providing a fan with a hollow axle, a hollow hub and solid blades, where the axle and hub (optionally just the axle, and optionally the blades in addition to the axle and hub) are fabricated from a heat conducting material so that heat transfer can occur in the fan as well as in the heat exchanger. In yet another envisaged implementation, one or more of (optionally, all of) the blades may not include a serpentine internal pathway but may instead simply be hollow bodies fluidly coupled to the hub so that working fluid can flow into and out of them for heat transfer with the ambient environment.

It will also be appreciated that the fluid pathway through the heat exchanger need not necessarily be provided by a pipe. The vanes could, in another implementation, be provided with an internal serpentine pathway (similar to that disclosed above for the blades). It is also envisaged that instead of a vaned heat exchanger, the system may employ a porous body (for example, something akin to a wire wool structure) as the heat exchanger, and/or for the heat exchanger to completely surround the fan.

It should also be remembered that the foregoing internal working fluid pathways for the blades are only illustrative, and that other pathway configurations may be adopted if desired. For example, the internal wall 71 does not necessarily have to be E-shaped, as it could be configured to provide a longer and/or more serpentine or otherwise tortuous working fluid pathway.

It should also be noted that whilst the accompanying claims set out particular combinations of features described herein, the scope of the disclosure is not limited to the particular combinations hereafter claimed, but instead extends to encompass any combination of features herein disclosed.

Finally, it should be noted that any element in a claim that does not explicitly state “means for” performing a specified function, or “steps for” performing a specific function, is not to be interpreted as a “means” or “step” clause as specified in 35 U.S.C. Sec. 112, par. 6. In particular, any use of “step of” in the claims appended hereto is not intended to invoke the provisions of 35 U.S.C. Sec. 112, par. 6.

1-27. (canceled)

28. A heat transfer system comprising:
a fan, and
a heat exchanger arranged relative to the fan so that the fan is operable to blow or draw air over and/or through the heat exchanger,
wherein the fan and the heat exchanger each include an internal pathway through which working fluid can flow, the respective internal pathways being coupled to one another so that working fluid can flow through the fan and the heat exchanger for heat transfer between the working fluid and air surrounding said heat transfer system.

29. The heat transfer system according to claim 28, wherein the fan comprises a hollow axle, a hollow hub fluidly coupled to the axle so that working fluid can flow through the axle and the hub, and a plurality of blades extending radially from the hub; at least said axle being of a heat conducting material so that heat transfer can occur between working fluid flowing through said axle and the air.

30. The heat transfer system according to claim 29, wherein said hollow hub and/or said blades is/are of a heat conducting material, and optionally at least one of said blades is hollow and fluidly coupled to said hub so that working fluid can flow into and out of said hollow blade for heat transfer with the air.

31. The heat transfer system according to claim 30, wherein one or more of said blades includes an internal blade pathway through which working fluid can flow, and said internal blade pathway includes a plurality of perturbators operable to increase perturbations in working fluid flowing through the internal blade pathway.

32. The heat transfer system according to claim 31, wherein said blade comprises one or more internal walls, said internal walls being configured to provide an internal blade pathway that is serpentine in one dimension within said blade, said internal blade pathway being serpentine in one dimension that extends lengthwise between a leading edge and a trailing edge of said blade.

33. The heat transfer system according to claim 31, wherein said blade comprises a plurality of internal walls, said internal walls being configured to provide an internal blade pathway that is serpentine in two dimensions within said blade, wherein said blade has a leading edge, a trailing edge, and first and second sidewalls extending between said leading and trailing edges; said internal blade pathway being serpentine in a first dimension that extends longitudinally between said leading edge and said trailing edge, and in a second dimension that extends transversely between said first and second sidewalls.

34. The heat transfer system according to claim 31, wherein said internal blade pathway comprises an inlet for ingress of working fluid and an outlet for egress of working fluid, wherein:
(i) said inlet is located in a first blade and said outlet is located in a second blade that is radially spaced from said first blade so that said internal blade pathway extends through more than one blade, or
(ii) said inlet and said outlet are located in the same blade so that said internal blade pathway extends through a single blade.

35. The heat transfer system according to claim 34, wherein said hub includes an internal baffle having a first side and a second side, wherein said baffle subdivides said hollow hub into a first manifold proximate said first side of said baffle and a second manifold proximate said second side of said baffle, each said manifold including a plurality of ports at spaced locations about a peripheral wall of the hub.

36. The heat transfer system according to claim 35, wherein said ports enable fluid communication between said hub and the inlet and the outlet of said internal blade pathway.

37. The heat transfer system according to claim 36, wherein a port in said first manifold is in fluid communication with said inlet, and a port in said second manifold is in fluid communication with said outlet.

38. The heat transfer system according to claim 37, wherein: (i) sidewalls of one or more of said blades are provided with a plurality of ribs, and/or (ii) an external surface of said hub is provided with a plurality of ribs.

39. The heat transfer system according to claim 29, wherein said blades include a rip region, and the tip region of at least one of said blades comprises a winglet.

40. The heat transfer system according to claim 28, wherein said heat exchanger defines a recess in which at least part of said fan is located.

41. The heat transfer system according to claim 28, wherein said fan is enclosed within a void defined inside said heat exchanger.

42. The heat transfer system according to claim 28, wherein said heat exchanger comprises a fluid permeable body, said internal pathway extending through said fluid permeable body.

43. The heat transfer system according to claim 28, wherein said internal pathway through said heat exchanger comprises a length of piping through which working fluid can flow for heat exchange between the pipe and the air.

44. The heat transfer system according to claim 43, comprising a plurality of vanes through which said length of piping extends, said vanes being thermally coupled to said piping.

45. An HVAC, Air Source Heat Pump or ORC system comprising a heat transfer system according to claim 28.

46. A heat transfer system comprising:
a fan, and
a heat exchanger arranged relative to the fan so that the fan is operable to blow or draw air over and/or through the heat exchanger,
wherein:
(i) the fan and the heat exchanger each include an internal pathway through which working fluid can flow, the respective internal pathways being coupled to one another so that working fluid can flow through the fan and the heat exchanger for heat transfer between the working fluid and air surrounding said heat transfer system;
(ii) the fan comprises a hollow axle, a hollow hub fluidly coupled to the axle so that working fluid can flow through the axle and the hub, and a plurality of blades extending radially from the hub;
(iii) said hollow hub and/or said blades is/are of a heat conducting material, and said blades are hollow and fluidly coupled to said hub so that working fluid can flow into and out of said hollow blades for heat transfer with the air;
(iv) said blades include an internal blade pathway through which working fluid can flow, and said internal blade pathway includes a plurality of perturbators operable to increase perturbations in working fluid flowing through the internal blade pathway;
(v) said blades each comprise a plurality of internal walls, said internal walls being configured to provide an internal blade pathway that is serpentine in two dimensions within each said blade, wherein said blade has a leading edge, a trailing edge, and first and second sidewalls extending between said leading and trailing edges; said internal blade pathway being serpentine in a first dimension that extends longitudinally between said leading edge and said trailing edge, and in a second dimension that extends transversely between said first and second sidewalls;
(vi) said internal blade pathway comprises an inlet for ingress of working fluid and an outlet for egress of working fluid, wherein: (a) said inlet is located in a first blade and said outlet is located in a second blade that is radially spaced from said first blade so that said internal blade pathway extends through more than one blade, or (b) said inlet and said outlet are located in the same blade so that said internal blade pathway extends through a single blade;
(vii) said hub includes an internal baffle having a first side and a second side, wherein said baffle subdivides said hollow hub into a first manifold proximate said first side of said baffle and a second manifold proximate said second side of said baffle, each said manifold including a plurality of ports at spaced locations about a peripheral wall of the hub; and
(viii) said ports enable fluid communication between said hub and the inlet and the outlet of said internal blade pathway.

47. An HVAC, Air Source Heat Pump or ORC system comprising a heat transfer system, said heat transfer system comprising:
a fan, and
a heat exchanger arranged relative to the fan so that the fan is operable to blow or draw air over and/or through the heat exchanger,
wherein:
(i) the fan and the heat exchanger each include an internal pathway through which working fluid can flow, the respective internal pathways being coupled to one another so that working fluid can flow through the fan and the heat exchanger for heat transfer between the working fluid and air surrounding said heat transfer system;
(ii) the fan comprises a hollow axle, a hollow hub fluidly coupled to the axle so that working fluid can flow through the axle and the hub, and a plurality of blades extending radially from the hub;
(iii) said hollow hub and/or said blades is/are of a heat conducting material, and said blades are hollow and fluidly coupled to said hub so that working fluid can flow into and out of said hollow blades for heat transfer with the air;
(iv) said blades include an internal blade pathway through which working fluid can flow, and said internal blade pathway includes a plurality of perturbators operable to increase perturbations in working fluid flowing through the internal blade pathway;
(v) said blades each comprise a plurality of internal walls, said internal walls being configured to provide an internal blade pathway that is serpentine in two dimensions within each said blade, wherein said blade has a leading edge, a trailing edge, and first and second sidewalls extending between said leading and trailing edges; said internal blade pathway being serpentine in a first dimension that extends longitudinally between said leading edge and said trailing edge, and in a second dimension that extends transversely between said first and second sidewalls.
